(19) United States
(12) Patent Application Publication
(10) Pub. No.: US 2010/0283525 A1
(43) Pub. Date: Nov. 11, 2010

(54) PHASE CONTROL DEVICE AND DATA COMMUNICATION SYSTEM USING IT

(76) Inventor: Takefumi Yoshikawa, Hyogo (JP)

Correspondence Address: MCDERMOTT WILL & EMERY LLP, 600 13TH STREET, NW, WASHINGTON, DC, 20005-3096, US

(21) Appl. No.: 12/811,489

(22) PCT Filed: Oct. 28, 2008
(86) PCT No.: PCT/JP2008/003060

§ 371 Date: Jul. 1, 2010

(30) Foreign Application Priority Data
Feb. 25, 2008 (JP) 2008-042904

(51) Int. Cl. H03K 5/13

(52) U.S. Cl. 327/237

(57) ABSTRACT

A phase control device that adjusts a phase of a clock receives a first clock, a second clock and a control code. The phase control device includes phase adjusters (PI-11, PI-12), PI-2 and PI-3 that output a clock of a phase corresponding to the control code. These phase adjusters are connected in a three-stages cascade. The control codes of these phase adjusters (PI-11, PI-12), PI-2 and PI-3 are varied in association with each other. Therefore, as compared with a case where a phase of a clock is adjusted by a phase adjuster alone, if a resolution (adjustment granularity) of each phase adjuster is defined as N, it is possible to reduce the adjustment granularity of a phase as small as N to the power of the number of the stages. Therefore, when the phase control device is used for a SSC, the peak power reduction value is improved.

### TECHNICAL FIELD

The present invention relates to a phase adjusting device that adjusts a phase of an internal clock of an LSI, and to a data communication system utilizing its phase adjusting function.

### BACKGROUND ART

In high speed interface LSIs of recent years, a phase of a clock is adjusted, and a clock recovery or Spread-Spectrum-clocking (SSC) is conducted in some cases (see non-patent document 1 for example).

A phase control device that adjusts a phase of a clock uses a phase interpolator PI as shown in FIG. 3(a), digital control codes PICTRL and NPICTRL are input to the phase interpolator PI, thereby interpolating the phase of a pair of differential clock inputs (A+, A−, B+ and B−), and clocks (OUT+ and OUT−) of a phase corresponding to the control codes are output as shown in FIG. 3(b).

When a phase of high speed data is to be adjusted using such a phase interpolator PI, the granularity of adjustment per one normal bit is about 10 ps. When a frequency is modulated with this granularity, if a clock is of a few tens MHz, 0.5% (5000 ppm), modulation can be carried out with a shift of about 10 ps every time, but if a clock is of 1.5 GHz, granularity of about 0.1 ps is required for 0.5% (5000 ppm) modulation as shown in FIG. 12. Therefore, in the conventional technique, a clock is not shifted every time, but is shifted once in several times so that a shift amount becomes about 0.1 ps as average.

### CITATION LIST

### Non-Patent Document

NON-PΔTENT DOCUMENT 1: M. Aoyama, K. Ogasawara, M. Sugawara, T. Ishibashi, T. Ishibashi, S. Shimoyama, K. Yamaguchi, and T. Yanagida, “3 Gbps, 5000 ppm Spread Spectrum SerDes PHY with frequency tracking Phase Interpolator for Serial ΔTA,” 2003 Symposium on VLSI Circuits Digest of Technical Papers pp. 107-110, June 2003.

### SUMMARY OF THE INVENTION

### Technical Problem

In the conventional technique, however, since the shifting operation is carried out intermittently, a peak power reduction value by frequency modulation remains about 5 dB.

When clock data recovery (CDR) is carried out using a phase adjuster such as the phase interpolator PI as in the conventional technique, the granularity of the phase shift becomes a stumbling block, and there is a speed-up limitation in clock recovery.

It is an object of the present invention to reduce the granularity of phase adjustment in a phase control device, to improve a peak power reduction value of the Spread-Spectrum-clocking (SSC), and to speed up the clock recovery.

### Solution to the Problem

To achieve the above object, according to the present invention, in the phase control device, phase adjusters are connected to each other in multistage in a cascade manner, and the control codes of the phase adjusters are varied in association with each other. With this, it is possible to reduce the phase adjusting amount as compared with a case where the phase adjuster is used alone.

That is, a phase control device includes phase adjusters that receive a first clock, a second clock and control codes, and that output a clock of a phase corresponding to the control code, the phase adjusters are connected to each other in multistage in a cascade manner, and the control codes of the multistage phase adjusters are varied in association with each other.

In the phase control device of the invention, the control codes of the multistage phase adjusters are periodically varied in time sequence, thereby modulating a frequency of an output clock with this period.

A data communication system of the invention includes the phase control device, and the phase control device is used for adjusting a phase of a clock.

The data communication system of the invention includes the phase control device, and a frequency of communication data is modulated by a clock from the phase control device.

In the data communication system of the invention, an adjusting amount of phase adjustment from the phase control device is dynamically varied in accordance with input data.

The data communication system of the invention further includes an equalizer that equalizes the input data, the input data is over sampled by a plurality of clocks to the phase adjusters, and intensity of the equalizer is set based on a result of the over sampling.

Therefore, according to the invention, as compared with a case where a phase is adjusted by a phase adjuster alone, if a resolution (adjustment granularity) of each phase adjuster is defined as N, it is possible to reduce the adjustment granularity of a phase as small as N to the power of the number of the stages. Therefore, when the phase control device is used for a SSC, the peak power reduction value is improved, and when the invention is applied to the clock recovery circuit, it is possible to speed up the processing.

That is, if a frequency of an output clock is modulated with this period by varying the control code of the phase adjuster periodically in time sequence, it is possible to reduce the peak power of the clock, and if the invention is used for the phase adjustment of a clock, it is possible to control the clock finely and thus, it is possible to speed up the data communication system.

According to the invention, the phase adjusting device is applied to the data communication system and a frequency of communication data is modulated. Therefore, it is possible to reduce the peak power of the electromagnetic radiation (EMI) from data in a transmission channel.

According to the invention, since the adjusting amount of the phase adjustment is dynamically varied, if the variation in frequency of input data is large when receiving data of the data communication system, the shifting amount of a clock can also be increased. Therefore, it is possible to enhance the following ability of a clock with respect to the input data, i.e., to enhance so-called jitter tolerance.

In addition, according to the invention, input data is over sampled, and intensity of the equalizer is set in accordance with a result thereof. Therefore, it is possible to control the equalizer in accordance with characteristics of an external transmission channel, and communication quality can be enhanced.

### ADVANTAGES OF THE INVENTION

As described above, the present invention allows fine resolution (adjustment granularity) of a phase of a phase adjuster as compared with a case where the phase is adjusted using the phase adjuster alone. Therefore, when the invention is used in the SSC, the peak power reduction value can be improved, and when the invention is applied to the clock recovery circuit, it is possible to speed up the processing.

### BRIEF DESCRIPTION OF THE DRAWINGS

FIG. 1 is a diagram showing a phase control device according to a first embodiment of the present invention;

FIG. 2 is a circuit diagram of a clock selector provided in the phase control device;

FIG. 3(a) is a circuit diagram of a phase interpolator provided in the phase control device, and FIG. 3(b) is a diagram showing a simulation result of phase interpolation carried out by the phase interpolator;

FIG. 4 is a circuit diagram of a code generator provided in the phase control device;

FIG. 5(a) is a state diagram showing states of a state machine provided in the phase control device, and FIG. 5(b) is a diagram showing a state of modulation of a frequency carried out by the state machine;

FIG. 6(a) is a diagram for explaining a state where Buddy Clock is added by ΔT by ΔT in phase adjustment of the phase control device and a phase shift is repeated, and FIG. 6(b) is a diagram for explaining a state of the phase adjustment when the Buddy Clock is shifted to 31ΔT;

FIG. 7 is an explanatory diagram of operation of a duty cycle collector provided in the phase control device;

FIG. 8 is a block diagram of a data communication system provided in the phase control device;

FIG. 9 is a block diagram of the phase control device (DPC) provided in the data communication system;

FIG. 10 is a state diagram showing states of a receiver provided in the data communication system;

FIG. 11 is a diagram showing a simulation result of jitter tolerance when a shift amount of a phase is dynamically varied in the receiver;

FIG. 12 is a conceptual diagram of frequency modulation;

FIG. 13(a) is a circuit diagram of an equalizer provided in the receiver, and FIG. 13(b) is a circuit diagram of a receiver amplifier provided in the equalizer; and

FIG. 14 is a diagram showing adjustment sequence of the equalizer.

### DESCRIPTION OF EMBODIMENTS

A preferred embodiment of the present invention will be described below in detail.

The embodiment of the invention described below does not improperly limit the contents of the invention described in claims, and it is not always true that all of configurations described in the embodiment are essential as solving means of the invention.

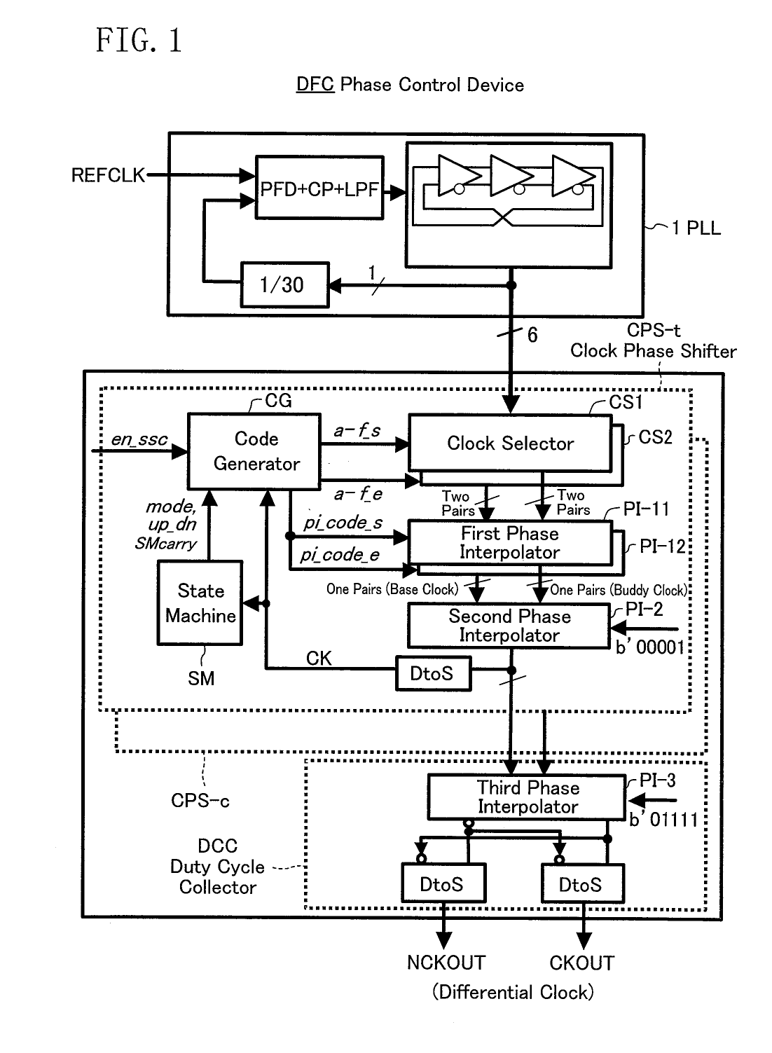

A phase control device DFC shown in FIG. 1 includes original and complement clock phase shifters CPS-t and CPS-c that receive six phase clocks of 750 MHz from a PLL1, and a duty cycle collector DCC.

Each of the clock phase shifters CPS-t and CPS-c includes two clock selectors CS1 and CS2 that select two pairs of differential clocks from the six phase clocks from the PLL1, and phase interpolators (PI-11, PI-12) and PI-2 that produce differential clocks whose phases are controlled from the differential clock selected by the clock selector. The phase interpolators (PI-11, PI-12) and PI-2 are connected in a cascade such that two phase interpolators (PI-11, PI-12) are located in a first stage and the one phase interpolator PI-2 is located in a second stage. Each of the clock phase shifters CPS-t and CPS-c further includes a code generator CG that supplies control codes a-f_s, a-f_e, pi_code_s and pi_code_e to the phase interpolators (PI-11, PI-12), PI-2 and the clock selectors CS1 and, CS2. Each of the clock phase shifters CPS-t and CPS-c further includes a state machine SM that controls the code generator CG. A clock whose phase from the phase interpolator PI-2 in the second stage is controlled is supplied to the duty cycle collector DCC.

The duty cycle collector DCC includes a phase interpolator PI-3 in a third stage that interpolates clocks from the original and complement clock phase shifters CPS-t and CPS-c, and a DS converter (DtoS) that differential/single converts a differential clock of the phase interpolator PI-3.

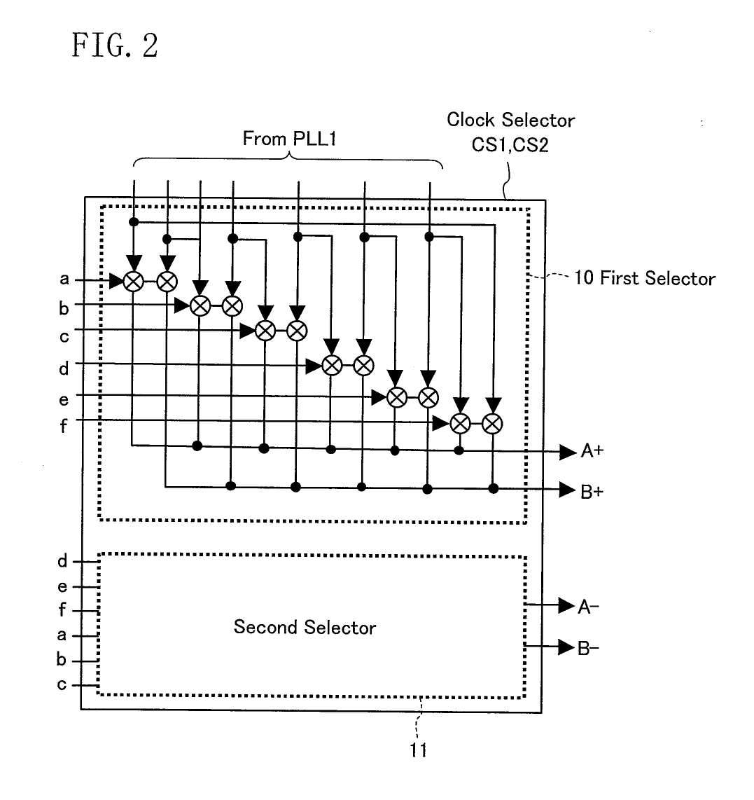

As shown in FIG. 2, the clock selectors CS1 and CS2 are combinations of a plurality of switches in a first selector 10 and a second selector 11 corresponding to the original and complement clock phase shifters CPS-t and CPS-c, and select two pairs of differential clocks (first and second clocks) A+, A−, B+ and B− in accordance with the control signals a-f.

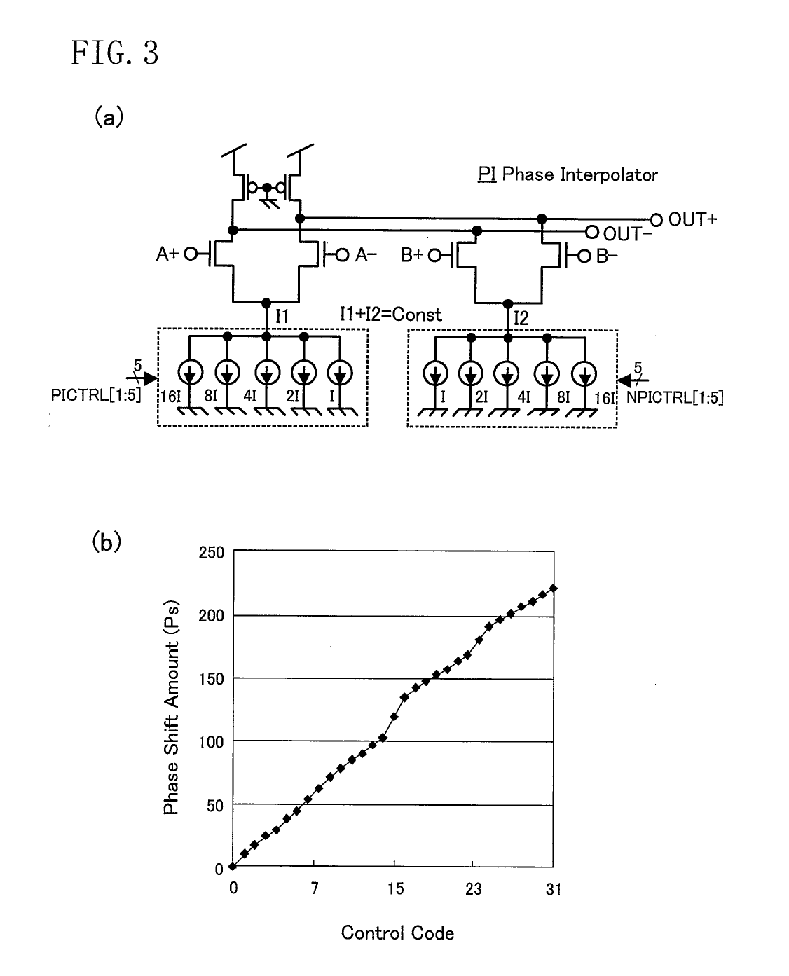

The phase interpolators (phase adjusters) (PI-11, PI-12), PI-2 and PI-3 of the three stages are conventional interpolators and adjusters as shown in FIG. 3, and five bit phase control is carried out. The phase interpolator is connected in the cascade as shown in FIG. 1 and is used, the first stage phase interpolators (PI-11, PI-12) have 32 levels of granularity, and the second stage phase interpolator PI-2 has 32×32=1024 levels of granularity. Since the third stage phase interpolator PI-3 in the duty cycle collector DCC selects the central phase for correcting the duty, the phase interpolator PI-3 has two levels of granularity and after all, the three stage phase interpolators can shift phases of 2048 levels of granularity.

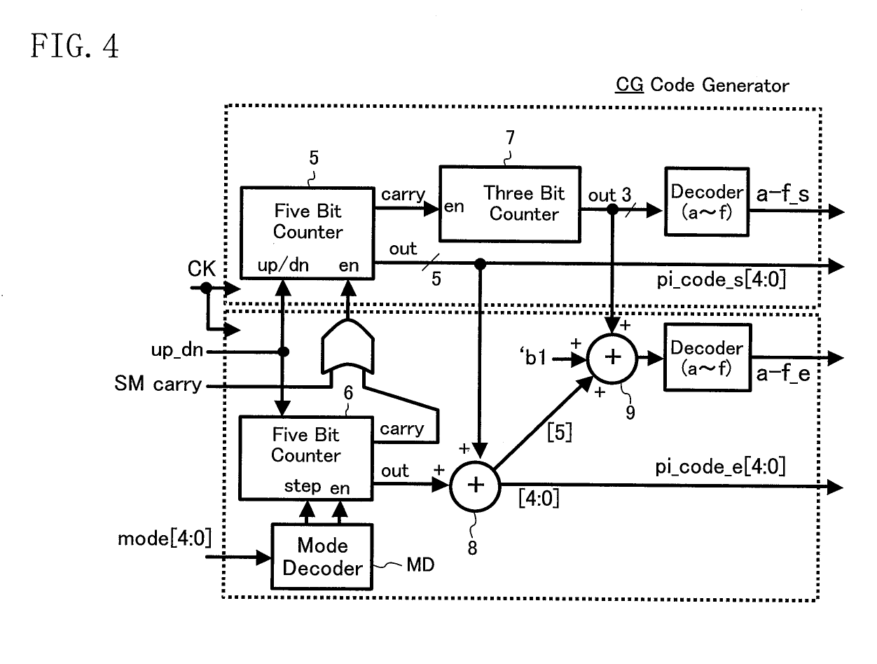

As shown in FIG. 4 the code generator CG includes five bit counters 5 and 6, a three bit counter 7, and two adders 8 and 9, and carries out a counting operation in accordance with the control signal up_dn, mode, SM_carry from the state machine SM. A mode decoder MD controls step of the counter, and switches between increment and decrement of the counter in accordance with an updown signal up_dn.

The control codes a-f_s and a-f_e of the clock selectors CS1 and CS2, and the control codes pi_code_s and pi_code_e of the first stage phase interpolators (PI-11, PI-12) have a bit relation in which the control code a-f_s and a-f_e of the clock selectors CS1 and CS2 are high, and the control codes pi_code_s and pi_code_e of the phase interpolators (PI-11, PI-12) are low. If the low control codes pi_code_s and pi_code_e become full, carry is set, and the higher control codes a-f_s and a-f_e are varied. This selects a clock to be interpolated in phase by the clock selectors CS1 and CS2 in general, and finely interpolates the phase interpolators (PI-11, PI-12) of the phase of the selected clock.

The code production is carried out for the total two pairs of differential clock base clocks, Buddy Clock from the phase interpolators (PI-11, PI-12).

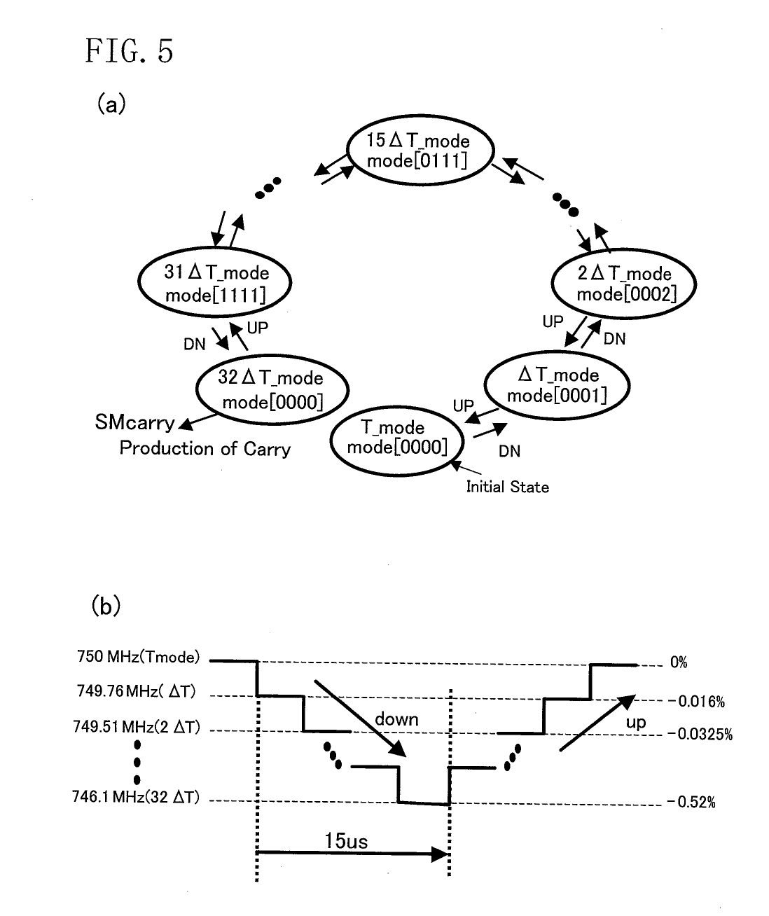

FIG. 5 is a state diagram showing states of the state machine SM. As shown in FIG. 5(a), the state machine SM includes 33 states, and in each state, a modulation amount (shift amount) of frequency as shown in FIG. 5(b) corresponds to 0 to 32ΔT. That is, peak realizes frequency modulation of 0.52% while finely modulating the frequency with a period of 30 μs.

The minimum shift amount is 2048 level of granularity with three stage phase interpolator as shown in calculation of the granularity. Since the differential clock that is further selected has T/3 (T is one bit time, 1T=667 ps) phase difference, a result is T/6144 (2048×3). That is, about 0.16 ps shift amount can be realized.

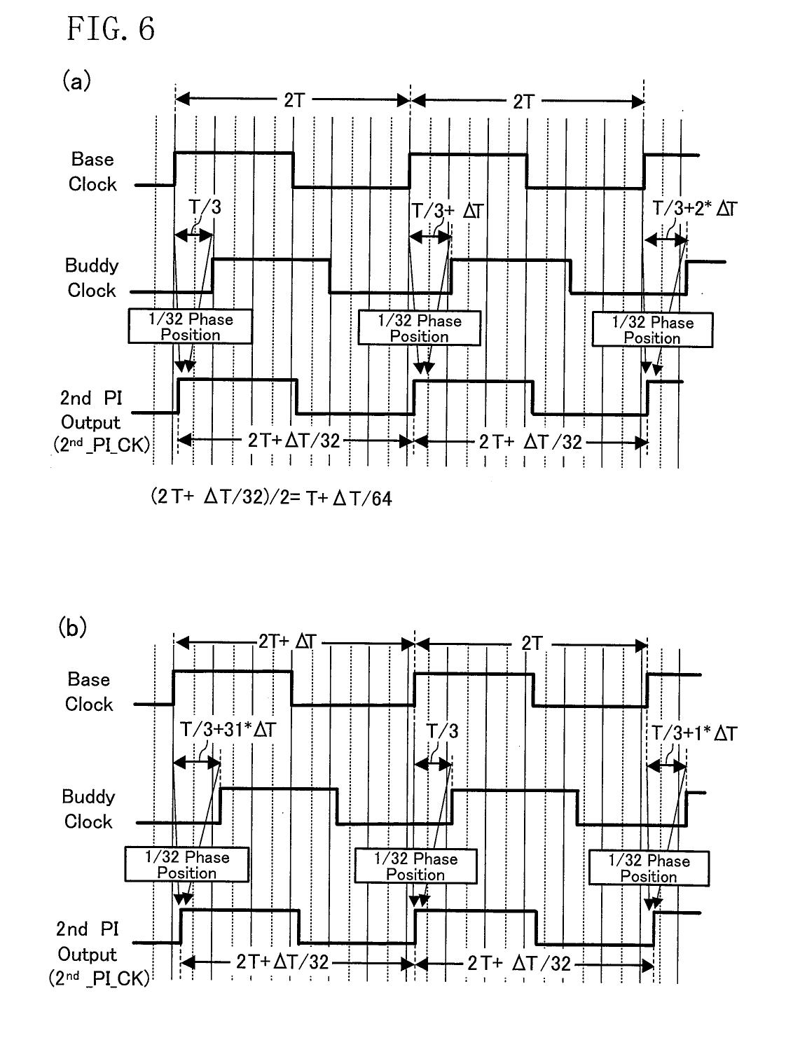

Operation of the phase control device DFC will be described. As shown in FIG. 6, the clock Base Clock, Buddy Clock of 750 MHz (2T cycles) are selected such that T/3 phase difference is generated, and as shown in FIG. 6(a), Buddy Clock is added by ΔT(T/3/32) by ΔT(T/3/32), and the phase shift is repeated. With this, the second state phase interpolator PI-2 outputs a clock whose frequency is modulated in accordance with the ΔT/32 shift amount. As shown in FIG. 6(b), when the Buddy Clock is shifted to 31ΔT, i.e., when the control code pi_code_e becomes full, the control code pi_code_e of the Base Clock is incremented and is shifted by ΔT. The shift amount of the Buddy Clock is returned to the ΔT, and increment is repeated. In this manner, the shift of T/3/32/32=T/3072 is realized by the two stage phase interpolators (PI-11, PI-12) and PI-2, and the phase shift of T/6144 can be finally realized by the duty cycle collector DCC.

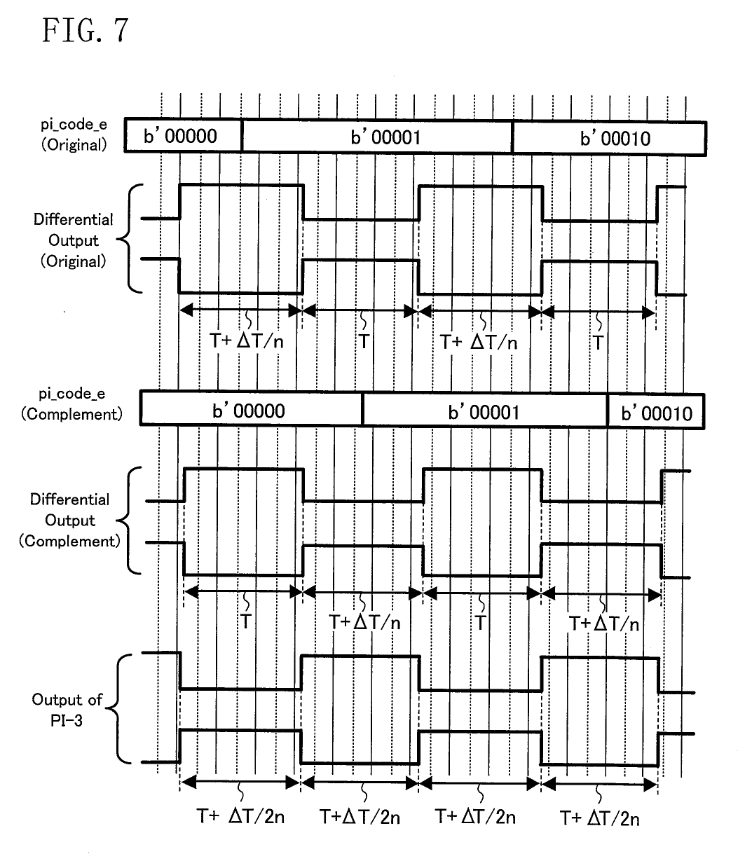

Next, the control code and the duty cycle collector DCC will be described with reference to FIG. 7. First, control code pi_code_e will be described. The control code pi_code_e is operated at 750 MHz, the original and complement clock is interleaved, thereby realizing substantially 1.5 GHz. Therefore, since the update of the control code is every 2T period, the time period of Hi and the time period of Lo of the clock are deviated from each other by ΔT. To compensate this, the duty cycle collector DCC selects the central phase, thereby aligning the time period of Hi and the period of Lo to each other, and correcting the duty.

As described above, the phase interpolators (PI-11, PI-12), PI-2 and PI-3 are combined in multiple stage in cascade, control is performed such that a rear stage of the control code is allocated to the lower LSB and the front stage is allocated to the upper MSB. With this, it is possible to extremely finely shift a phase. With this, even if a clock is as fast as 1.5 GHz, it is possible to shift the phase every time and to realize clock frequency modulation finely and directly.

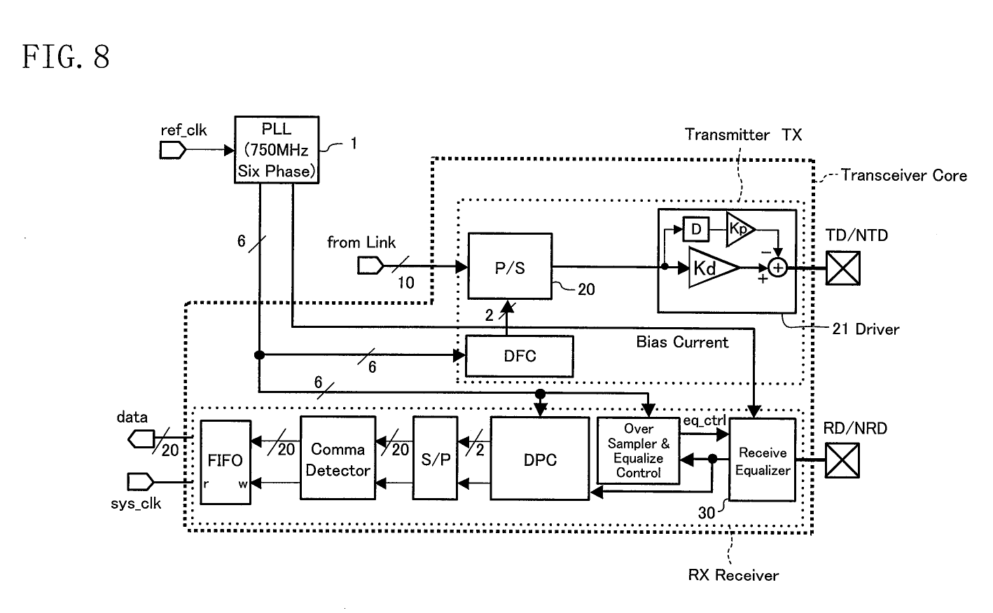

A data communication system utilizing the phase control device DFC is shown in FIG. 8.

The data communication system shown in FIG. 8 includes a six phase PLL1, a transmitter TX, and a receiver RX.

The transmitter TX includes the phase control device DFC, operates a parallel/serial converter (PS) 20 by a clock whose frequency is modulated by the above-described operation, and data TD/NTD are sent from a driver 21. Since the frequency of the data is finely modulated, the peak poser of EMI in the sent data is reduced.

The receiver RX includes a phase control device DPC that is different from the phase control device DFC provided in the transmitter TX. The phase control device DPC shifts a phase of a clock in accordance with a phase of input data and realizes a clock recovery.

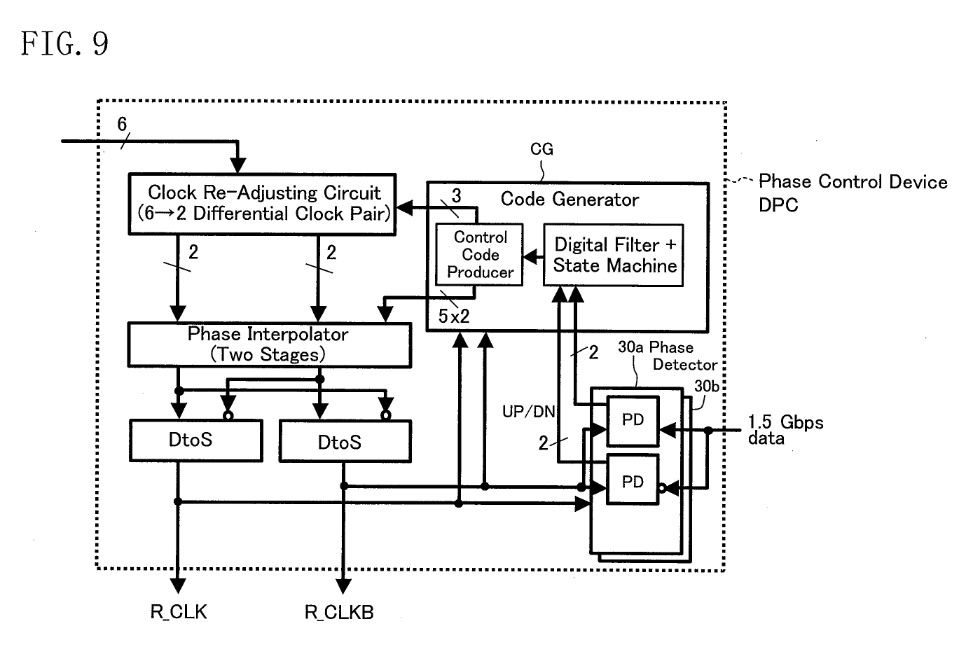

As shown in FIG. 9, the phase control device DPC operates basically in the same manner as that of the phase control device DFC of the transmitter TX, but a code generator CG produces a control code as a result of detection of phase detectors 30a and 30b. That is, input data and recovery clock R_CLK are compared with each other, its delay/advance UP/DN is filtered by a digital filter, a state of the state machine is moved by its result, and the control code is produced.

With this, a recovery clock suitable for the phase of the input data is produced, clock recovery is realized, and high speed and stable operation can be realized with an extremely small shift amount.

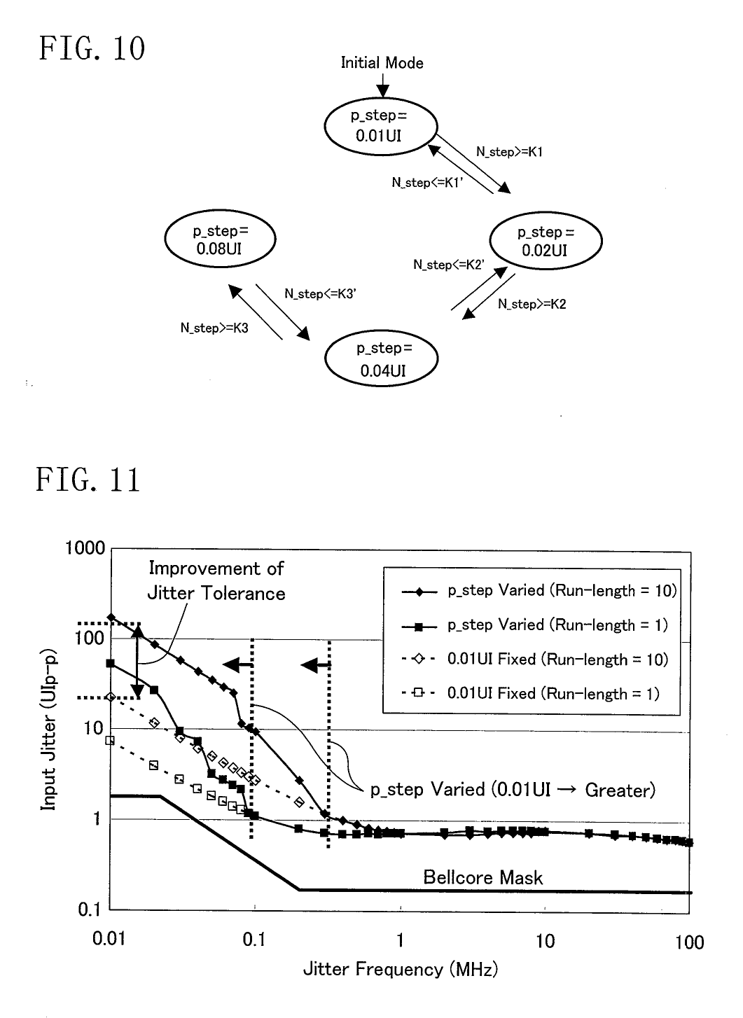

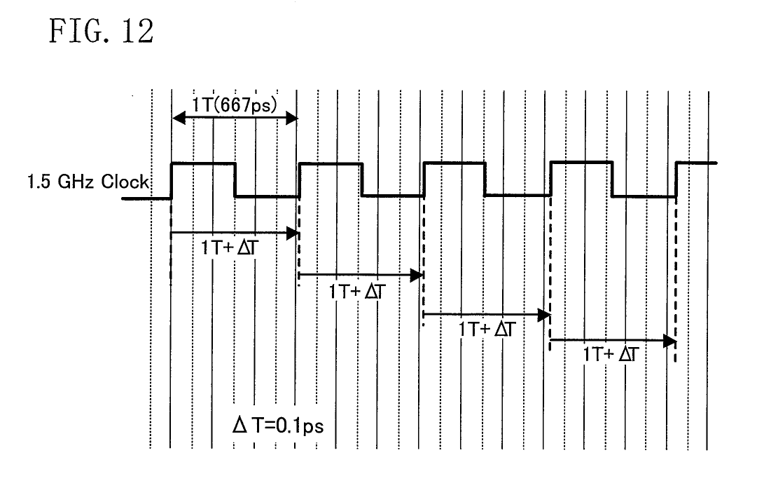

FIG. 10 is a state diagram of states on the side of the receiver RX. The shift amount of the phase is varied depending upon the state, the times N_step in which delay DN and advance UP are continuous are counted, and state transition is carried out.

That is, in the initial state (0.01U1), a shift amount is very small, but if delay or advance continues more than predetermined times (K1), transition is made to a state (0.02UI) where the shift amount is doubled. This is because if advance or delay continues, it is determined that the deviation in frequency is large, and the shift amount is increased so as to follow the deviation. This idea is applied, four states are mounted, and the shift amount is always increased or reduced. Reference times K1, K2 and K3 of the state transition can be programmed. The reference times have a relation of K1<K2<K3.

If the shift amount of the phase can be varied dynamically in this manner, the following ability on the side of low frequency is enhanced as compared with a case where the shift amount is fixed to a small value (0.01UI) as shown in the simulation result in FIG. 11. This is because that the repetition of delay and advance is counted and the shift amount is varied and thus, as the frequency is lower (counted value is greater), the following ability is enhanced.

If the shift amount is fixed to a large value, since the stability on the side of the high frequency is deteriorated, when the frequency is higher, i.e., when the counted value is smaller, the shift amount is made smaller.

That is, by varying the shift amount dynamically, the stability on the high frequency side and following ability on the low frequency side are both satisfied.

In FIG. 8, the receiver RX is provided with an equalizer 30 that equalizes input data, the intensity of the equalizer 30 is varied based on an over sampling result using a multiphase clock from the PLL1, thereby inputting excellent data to the phase control device DPC.

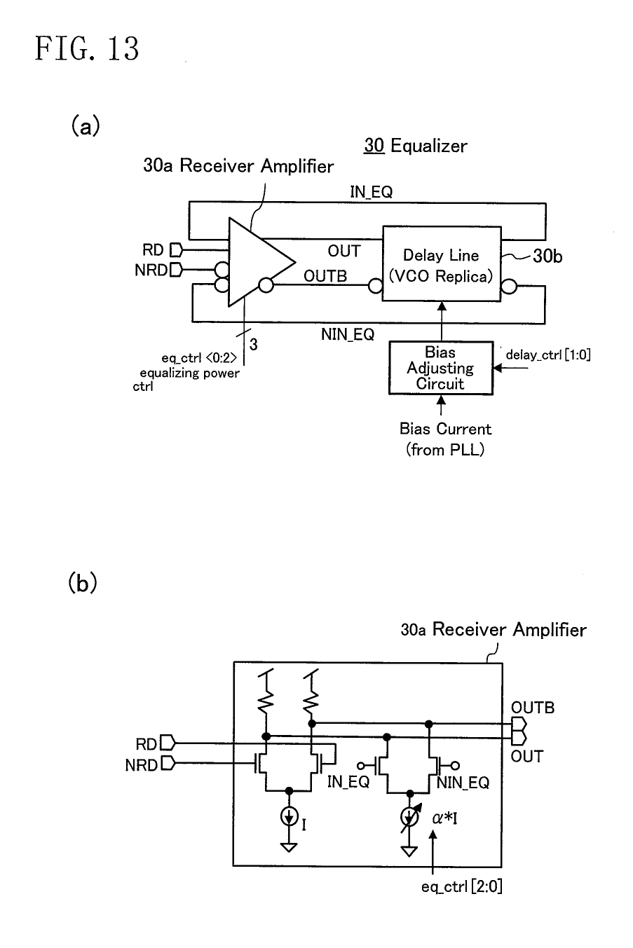

As shown in FIG. 13(a), the equalizer 30 subtracts an input signal that is delayed by 1 bit time (1T) using a receiver amplifier 30a, and is formed as a so-called IIR type equalizer. As shown in FIG. 13(a), the delay of 1 bit time (1T) is produced by giving bias current from the PLL1 to a delay line 30b of the VCO replica. This delay can finely be adjusted by adjustment bit delay_ctrl from outside. As shown in FIG. 13(b), the receiver amplifier 30a provides a signal sent through the delay line 30b to a level suitable for the digital control bit eq_ctrl, subtracts the same from input data, and carries out IIR type equalization.

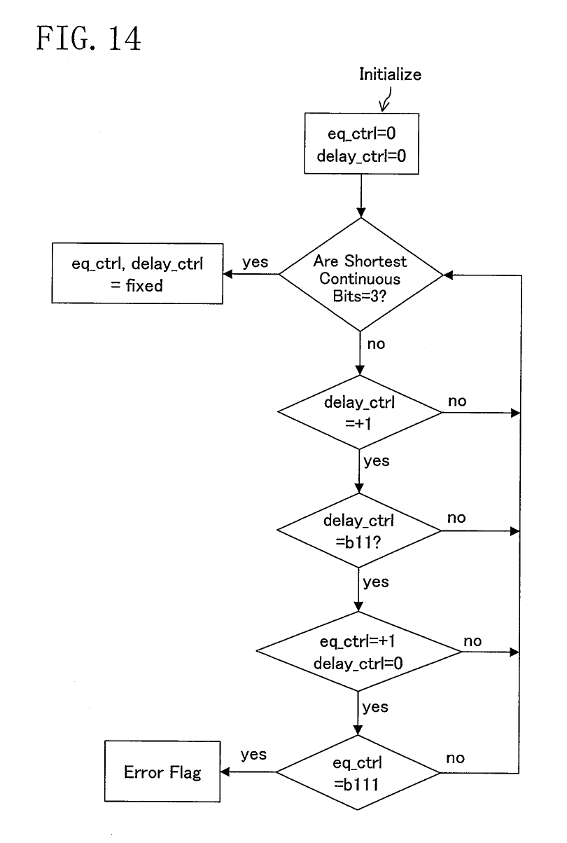

The control of the control bits delay_ctrl and eq_ctrl is as shown in FIG. 14. First, an initial value is 0, input data is over sampled triple, the shortest continuous bit length is found from the sampled results, and it is determined whether the shortest continuous bit length is 3. If the shortest continuous bit length is 3, the control bit is fixed. If the shortest continuous bit length is not 3, the delay_ctrl is incremented, and this is repeated until the shortest continuous bit length becomes 3. If the delay_ctrl becomes 11 (in the case of two bit length), the delay_ctrl is returned to 0, eq_ctrl is incremented and this is repeated until the shortest continuous bit length becomes 3. If there is no point where the shortest continuous bit length becomes 3, an error flag is set.

As described above, according to this embodiment, since extremely fine or small phase shift can be realized, even if a clock has high speed, it is possible to directly shift a phase every time, and to finely modulate a frequency. With this, as compared with the conventional intermittent shifting operation of a phase, a peak power of EMI can excellently be reduced. With the fine shifting, it is possible to adjust an edge of a clock at an optimal point even if data has short bit time, it is possible to enhance the performance of the clock recovery and to speed up the processing. By dynamically varying the shift amount, both stability on the side of high frequency in jitter tolerance and following ability on the side of low frequency can be satisfied.

### INDUSTRIAL APPLICABILITY

According to the present invention, as described above, it is possible to reduce the resolution (adjustment granularity) of a phase of a phase adjuster as compared with a case where a phase is adjusted using a phase adjuster alone. Therefore, it is possible to improve a peak power reduction value when the invention is used in SSC, and to speed up the processing when the invention is applied to the clock recovery circuit, and the invention is effective as a phase adjusting device. It is possible to reduce the peak power of electromagnetic radiation (EMI) from data in a transmission channel using the phase adjusting device, and the invention can be applied to a data communication system that enhances jitter tolerance.

### DESCRIPTION OF REFERENCE CHARACTERS

DFC, DPC Phase Control Device
PI-11, PI-12,
PI-2, PI-3 Phase Interpolator (Phase Adjuster)
CPS-t, CPS-c Clock Phase Shifter
DCC Duty Cycle Collector
DtoS Differential Single Converter
CS1, CS2 Clock Selector
CG Code Generator
SM State Machine
TX Transmitter
RX Receiver
30 Equalizer

1. A phase control device having phase adjusters that receive a first clock, a second clock and control codes, and that output a clock of a phase corresponding to the control code, wherein
the phase adjusters are connected to each other in multistage in a cascade manner, and
the control codes of the multistage phase adjusters are varied in association with each other.

2. The phase control device of claim 1, wherein
the control codes of the multistage phase adjusters are periodically varied in time sequence, thereby modulating a frequency of an output clock with this period.

3. A data communication system comprising the phase control device of claim 1, wherein
the phase control device is used for adjusting a phase of a clock.

4. A data communication system comprising the phase control device of claim 2, wherein
a frequency of communication data is modulated by a clock from the phase control device.

5. The data communication system of claim 3, wherein
an adjusting amount of phase adjustment from the phase control device is dynamically varied in accordance with input data.

6. The data communication system of claim 5, further comprising an equalizer that equalizes the input data,
the input data is over sampled by a plurality of clocks to the phase adjusters, and intensity of the equalizer is set based on a result of the over sampling.
